(19) United States
(12) Patent Application Publication
(10) Pub. No.: US 2014/0159053 A1
(43) Pub. Date: Jun. 12, 2014

(54) SIC TRENCH GATE TRANSISTOR WITH SEGMENTED FIELD SHIELDING REGION AND METHOD OF FABRICATING THE SAME

(71) Applicant: INDUSTRIAL TECHNOLOGY RESEARCH INSTITUTE, Hsinchu (TW)

(72) Inventors: Young-Shying Chen, Hsinchu City (TW); Chien-Chung Hung, Hsinchu City (TW); Cheng-Tyng Yen, Kaohsiung City (TW); Chwan-Ying Lee, Hsinchu City (TW)

(73) Assignee: Industrial Technology Research Institute, Hsinchu (TW)

(21) Appl. No.: 13/850,306

(22) Filed: Mar. 26, 2013

(30) Foreign Application Priority Data
Dec. 7, 2012 (TW) 101146103

(51) Int. Cl. H01L 29/739; H01L 29/66

(52) U.S. Cl. CPC H01L 29/7395; H01L 29/66893
USPC 257/77; 438/192

(57) ABSTRACT

A SiC trench gate transistor with segmented field shielding region is provided. A drain region of a first conductivity type is located in a substrate. A first drift layer of the first conductivity type is located on the substrate and a second drift layer of the first conductivity type is located on the first drift layer. A base region of a second conductivity type is located on the second drift layer. A gate trench is located between the adjacent base regions. A plurality of segmented field shielding regions of the second conductivity type is placed under a bottom of the gate trench and the space between segmented field shielding regions is the first drift region. A gate dielectric layer is located on a bottom and at a sidewall of the gate trench and a trench gate is formed in the gate trench.

### CROSS-REFERENCE TO RELATED APPLICATION

This application claims the priority benefit of Taiwan application serial no. 101146103, filed on Dec. 7, 2012. The entirety of the above-mentioned patent application is hereby incorporated by reference herein and made a part of this specification.

### TECHNICAL FIELD

The disclosure relates to a SiC trench gate transistor with segmented field shielding region and a method of fabricating the same.

### BACKGROUND

A wide bandgap material of SiC has characteristics of a high breakdown field, a high thermal conductivity coefficient and a low intrinsic concentration, etc., superior than that of Si. Since the SiC has the characteristic of high breakdown field, an epitaxial drift layer of a SiC power component may have a higher doping concentration and a thinner thickness, which greatly reduces an on-state resistance Ron and decreases an on-state current loss; and the low intrinsic concentration may also greatly decrease an off-state current loss. Moreover, the high thermal conductivity coefficient of the SiC results in a fact that the SiC power component is more suitable for operations for a high-temperature environment than that of Si, which avails simplifying a design of a cooling module of the system, so as to decrease the cost and size of the cooling module. The SiC power components are now used to replace or used in collaboration with the Si power components for applying in a power module such as a DC-DC converter or a DC-AC inverter, etc. with a rated voltage of 600V or 1200V, by which energy conversion efficiency is enhanced from 95% to 99%.

A breakdown field (3×10⁶ V/cm) of SiC is higher than a breakdown field (6×10⁵ V/cm) of Si, and is close to a breakdown field (5-8×10⁶ V/cm) of a gate oxide layer. Therefore, in case of SiC breakdown of SiC trench MOS, the gate oxide layer field (12-15×10⁶V/cm) at the bottom and bottom corner of a gate trench exceeds the breakdown field of the gate oxide layer, which results in destructive breakdown and cause a reliability problem of the gate oxide layer. Existent documents have provided a method of adding a field shielding region completely covering the bottom of the gate trench at the bottom of the gate trench type gate to decrease an electric field, though according to such method, a junction field effective transistor (JFET) is formed between a body region and the field shielding region, causing an additional series-connected resistor therebetween, so as to increase an on-state resistance.

### SUMMARY

An embodiment of the disclosure provides a SiC trench gate transistor with segmented field shielding region, which includes a drain region, a first drift layer, a second drift layer, a plurality of base regions, a plurality of source regions, a plurality of body regions, a plurality of trench gates, a plurality of segmented field shielding regions, and a gate dielectric layer. The drain region of a first conductivity type is located on a substrate. The first drift layer of the first conductivity type is located on the substrate. The second drift layer of the first conductivity type is located on the first drift layer. The base regions of a second conductivity type are located on the second drift layer. A plurality of gate trenches is located between the adjacent base regions. The gate dielectric layer is disposed on a bottom and at a sidewall of the gate trench, and the trench gates are formed in the gate trenches. The source regions of the first conductivity type are disposed in the base regions and located adjacent to the sidewalls of the gate trenches. The body regions of the second conductivity type are disposed in the base regions. The segmented field shielding regions of the second conductivity type are disposed under a bottom of the gate trenches and the first drift layer is located between the segmented field shielding regions.

An embodiment of the disclosure provides a method of fabricating a SiC trench gate transistor with segmented field shielding region, which includes following steps. A drain region is formed in a substrate, where the drain region is of a first conductivity type. A first drift layer is formed on the substrate, where the first drift layer is of the first conductivity type. A plurality of floating segmented field shielding regions is formed in the first drift region, where the segmented field shielding regions are of a second conductivity type. A second drift layer is formed on the first drift layer, where the second drift layer is of the first conductivity type. A base region is formed on the second drift layer, where the base region has the second conductivity type. A source region is formed in the base region, where the source region is of the first conductivity type. A body region is formed in the base region, where the body region is of the second conductivity type. A gate trench pattern is defined on a surface of the substrate, and the source region, the base region, the second drift layer and a part of the first drift layer in the gate trench pattern are removed to form a gate trench. A gate dielectric layer is formed on a sidewall and a bottom surface of the gate trench. A trench gate is formed in the gate trench.

In order to make the aforementioned and other features and advantages of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a top view of a SiC trench gate transistor with segmented field shielding region according to an embodiment of the disclosure.

FIG. 2 is a three-dimensional view of a region R in FIG. 1.

FIGS. 3A-3G are cross-sectional views of fabricating a SiC trench gate transistor with segmented field shielding region according to an embodiment of the disclosure.

FIG. 4 illustrates a simulation result of trench gate transistors of an example 1 and a comparison example 1 by comparing doping concentrations of a surface of a gate oxide layer at a position apart from a surface of a source region by 0.75 μm.

FIG. 5A illustrates a simulation result of trench gate transistors of the example 1 and the comparison example 1 by comparing characteristic curves of a drain current (ID) and a gate voltage (VG) in case of a drain voltage of 0.1V.

FIG. 5B illustrates a simulation result of trench gate transistors of the example 1 and the comparison example 1 by comparing characteristic curves of a drain current (ID) and a gate voltage (VG) under various gate voltages (VG).

FIG. 6 illustrates a simulation result of trench gate transistors of a comparison example 2 and a comparison example 3 by comparing characteristic curves of a drain current (ID) and a gate voltage (VG) under various gate voltages (VG).

FIG. 7A is a cross-sectional view of the trench gate transistor of the example 2, which simulates a field strength distribution at peripheral of the gate trench in case that a gate voltage VG=0V and a drain voltage is a breakdown voltage (i.e. VD=1525V).

FIG. 7B is a cross-sectional view of the trench gate transistor of the comparison example 2, which simulates a field strength distribution at peripheral of the gate trench in case that the gate voltage VG=0V and the drain voltage is the breakdown voltage (i.e. VD=1525V).

FIG. 7C is a cross-sectional view of the trench gate transistor of the comparison example 3, which simulates a field strength distribution at peripheral of the gate trench in case that the gate voltage VG=0V and the drain voltage is the breakdown voltage (i.e. VD=1525V).

FIG. 8 illustrates a simulation result of trench gate transistors of the example 2, the comparison example 2 and the comparison example 3 by comparing field strength distributions of a gate dielectric layer on a bottom of a gate trench in case that a drain voltage is a breakdown voltage (i.e. VD=1525V) during turn-off.

FIG. 9 illustrates a simulation result of trench gate transistors of the example 2, the comparison example 2 and the comparison example 3 by comparing field strength distributions of a gate dielectric layer on a bottom of a gate trench in case that a drain voltage is a rated voltage (i.e., VD=1200V) during turn-off.

FIG. 10 illustrates a simulation result of trench gate transistors of the example 2, the comparison example 2 and the comparison example 3 by comparing characteristic curves of a drain current (ID) and a drain voltage (VD) during turn-off.

### DETAILED DESCRIPTION OF DISCLOSED EMBODIMENTS

In the disclosure, SiC trench gate transistor with segmented field shielding region is provided. The segmented field shielding regions are disposed under the gate trenches, and an electrical property the segmented field shielding regions is kept floating. During turn-off, a junction barrier is formed in a depletion region at a junction of the field shielding region and the first drift layer, which effectively decreases SiC field strength at the bottom and bottom corner of the gate trench without the field shielding region, so as to decrease the field strength of the gate dielectric layer at the bottom and bottom corner of the gate trench without the field shielding region to improve reliability. During turn-on, since the electrical property of the field shielding region is kept floating, a current is still conducted, and a non-field shielding region can still provide a normal turn-on current, which may compensate a current loss of the portion with the segmented field shielding region caused by series resistance of junction field effective transistor (JFET).

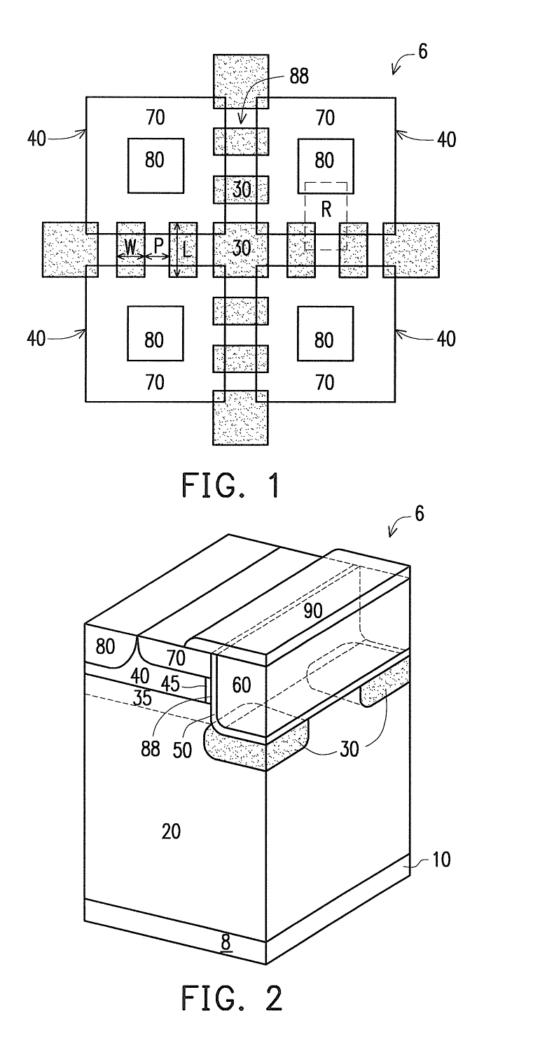

FIG. 1 is a top view of a SiC trench gate transistor with segmented field shielding region according to an embodiment of the disclosure. FIG. 2 is a three-dimensional view of a region R in the SiC trench gate transistor with segmented field shielding region of FIG. 1.

Referring to FIG. 1 and FIG. 2, the SiC trench gate transistor with segmented field shielding region 6 has a base region 40, and a body region 80 is disposed on the base region 40 in the center, and a source region 70 is disposed at peripheral of the body region 80. A gate trench 88 is formed between adjacent base regions 40. A plurality of segmented field shielding regions 30 is disposed under a bottom of the gate trench 88.

In detail, the SiC trench gate transistor with segmented field shielding region 6 includes a drain region 10, a first drift layer 20, a second drift layer 35, a base region 40, a source region 70, a body region 80, an embedded channel 45, a gate dielectric layer 50, a trench gate 60, a plurality of segmented field shielding regions 30, and a passivation layer 90.

The SiC trench gate transistor with segmented field shielding region 6 is fabricated on a substrate 8, in the embodiment, the substrate 8 includes a 4H or 6H—SiC substrate, and is of a first conductivity type to serve as the drain region 10. The first conductivity type of the substrate 8 is an n-type, which is, for example, doped with nitrogen, and a doping concentration thereof can be 1×10¹⁹-5×10¹⁹ cm⁻³.

The first drift layer 20 is of the first conductivity type, and is disposed on the substrate 8. The first conductivity type of the first drift layer 20 is the n-type, which is, for example, doped with phosphorus, and a doping concentration thereof can be 1×10¹⁵-1×10¹⁶ cm⁻³.

The second drift layer 35 is of the first conductivity type, and is disposed on the first drift layer 20. The first conductivity type of the second drift layer 35 is the n-type, which is, for example, doped with phosphorus, and a doping concentration thereof is equal to or greater than that of the first drift layer 20, which is, for example, 6×10¹⁵ cm³.

A plurality of the base regions 40 of the second conductivity type is located on the second drift layer 35, and the gate trenches 88 are located between adjacent base regions 40. The second conductivity type of the base region 40 is p-type, which is, for example, doped with boron, and a doping concentration thereof is, for example, 8.0×10¹⁶-3.0×10¹⁷ cm⁻³, and a thickness thereof is, for example, 0.8-1.0 μm. A top view pattern of the base region 40 may present various shapes. In an embodiment, the base region 40 is a square (shown in FIG. 1), though the disclosure is not limited thereto.

The source region 70, which is of the first conductivity type, is formed on a surface of the base region 40, and is located adjacent to a sidewall of the gate trench 88. The first conductivity type of the source region 70 is n-type, which is, for example, doped with nitrogen, and a doping concentration thereof is, for example, 1.0×10¹⁹-5.0×10¹⁹ cm⁻³, and a junction depth thereof is, for example, 0.2-0.4 μm.

A width of the gate trench 88 is, for example, 1.5-3.0 μm, and a depth thereof is at least the same as that of the bottom of the second drift layer 35, or greater than that of the bottom of the second drift layer 35. In the embodiment, the gate trench 88 penetrates through the second drift layer 35 from the surface of the base region 40 and extends to the first drift layer 20, and a bottom corner of the gate trench 88 is generally an obtuse angle or a round angle.

The gate dielectric layer 50 is disposed at a sidewall and on a bottom of the gate trench 88 to isolate the source region 70, the base region 40, the second drift layer 35, the first drift layer 20, the segmented field shielding region 30 and the trench gate 60. A material of the gate dielectric layer 50 is, for example, silicon oxide or silicon oxynitride; or a high dielectric constant material such as HfO₂, HfAlO, HfW₂, or Al₂O₃, etc.

The trench gate 60 is located in the gate trench 88. The trench gate 60 can be of the first conductivity type, and a material of the trench gate 60 of the first conductivity type is, for example, n-type poly-Si. The trench gate 60 can be of the second conductivity type, and a material of the trench gate 60 is, for example, p-type poly-Si. A material of the trench gate 60 also can be a stacked layer including metal, alloy, metal silicide or a combination thereof. The metal is, for example, Ni, Ti, Mo, Al or Pd, etc. The alloy is, for example, TiW and NiTi, etc. The metal silicide is, for example, formed by the above metal or alloy processed with suitable heat treatment and the poly-Si. In the present embodiment, a material of the trench gate 60 of the first conductivity type is n-type poly-Si, which is, for example, doped with phosphorus, and a doping concentration thereof is, for example, 1.0×10¹⁹-5.0×10¹⁹ cm⁻³.

The body region 80, which is of the second conductivity type, is foamed on the surface of the base region 40, and is surrounded by the source region 70. In the embodiment, the second conductivity type of the body region 80 is p-type, which is, for example, doped with aluminium, and a doping concentration thereof is, for example, 1.0×10¹⁹-5.0×10¹⁹ cm⁻³, and a junction depth thereof is, for example, 0.4-0.6 μm.

The embedded channel 45 is of the first conductivity type, and is located under the source region 70 and in the base region 40 on the sidewall of the gate trench 88. In the embodiment, the first conductive type of the embedded channel 45 is n-type, which is, for example, doped with nitrogen or phosphorus, and a doping concentration thereof is, for example, 4.0×10¹⁶-2.0×10¹⁷ cm⁻³, and a thickness thereof is, for example, 30-80 nm. The embedded channel 45 can effectively adjust a turn-on threshold voltage and improve channel electron mobility, so as to achieve an effect of reducing a channel resistance.

The passivation layer 90 covers the source region 70, the body region 80, the gate dielectric layer 50 and the trench gate 60. A material of the passivation layer 90 is, for example, silicon nitride (SiNx), low temperature silicon oxide, or silicon oxide formed by tetraethoxysilane (TEOS) serving as a reaction gas, or a stacked layer formed by a combination of silicon nitride and silicon oxide. In the silicon nitride SiNx, a proportion x of nitrogen and oxygen can be any possible stoichiometric coefficient.

The segmented field shielding regions 30 is of the second conductivity. In the embodiment, the second conductivity type of the segmented field shielding region 30 is p-type, which is, for example, doped with aluminium, and a doping concentration thereof is, for example, 2.0×10¹⁸-1.0×10¹⁹ cm⁻³, and a junction depth thereof is, for example, 0.5-0.6 μm. The segmented field shielding regions 30 are located under the bottom of the gate trench 88 and are disposed along a length direction of the gate trench 88. In detail, the segmented field shielding regions 30 of the embodiment are disposed in the first drift layer 20 under the bottom of the gate trench 88 in a floating island manner, and the space between the segmented field shielding regions 30 is the first drift region 20, and the segmented field shielding regions 30 are not connected to each other. A length (L) of each of the segmented field shielding regions 30 can be extended to the bottom of the base region 40, and the second drift layer 35 is located therebetween for isolation. The length (L), a width (W) and a pitch (P) of each of the segmented field shielding regions 30 can be the same or different, and can be adjusted according to an actual requirement, which avails effectively decreasing the field strength of the gate dielectric layer 50 at the bottom and bottom corner of the gate trench 88 without the segmented field shielding region 30, and the non-field shielding region can still provide a normal turn-on current for compensating a current loss of the portion with the segmented field shielding region 30 caused by series-connected resistor formed of junction field effective transistor (JFET), which is also included in the disclosure. In the embodiment, the pitch (P) between the adjacent segmented field shielding regions 30 is, fore example, 1.0-2.0 μm. However, the disclosure is not limited thereto, and the length (L), the width (W) and the pitch (P) of each of the segmented field shielding regions 30 can be designed according to an actual requirement.

In the SiC trench gate transistor 6 with segmented field shielding region 30, since the second drift layer 35 is located between the bottom of the base region 40 and the surface of the first drift layer 20, the electrical property of the segmented field shielding region 30 is kept floating, which may decrease the series resistance of the JFET between the segmented field shielding region 30 and the base region 40. Moreover, since the electrical property of the segmented field shielding region 30 is kept floating, in the turn-on operation, regardless of the portion with the segmented field shielding region 30 or the portion without the segmented field shielding region 30 (the first drift layer 20 between the adjacent segmented field shielding regions 30) can all conduct current. Although the portion with the segmented field shielding region 30 may cause the current loss due to the series resistance of the JFET, it can still conduct current; the portion without the segmented field shielding region 30 (the first drift layer 20 between the adjacent segmented field shielding regions 30) can provide normal turn-on current to compensate the current loss of the portion with caused by the series resistance of the JFET. During turn-off, a depletion region at junction between the portion with the segmented field shielding region 30 and the first drift layer 20 may form a junction barrier, which effectively decreases a SiC field strength at the bottom and bottom corner of the gate trench 88 without the segmented field shielding region 30, so as to decrease the field strength of the gate dielectric layer 50 at the bottom and bottom corner of the gate trench 88 to improve reliability.

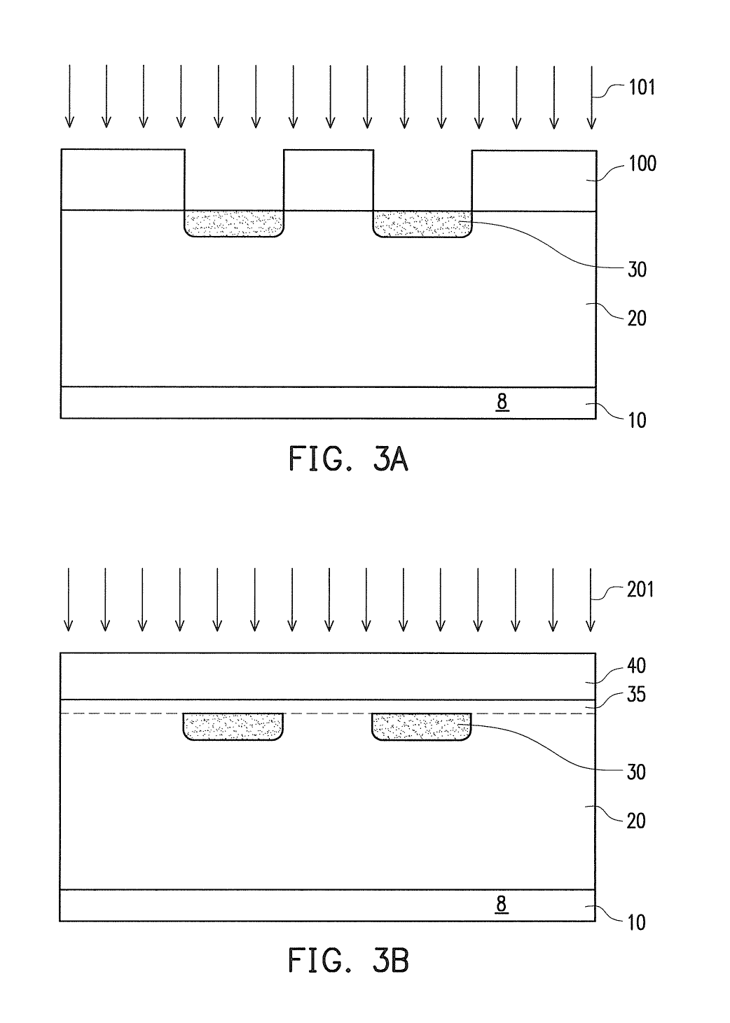

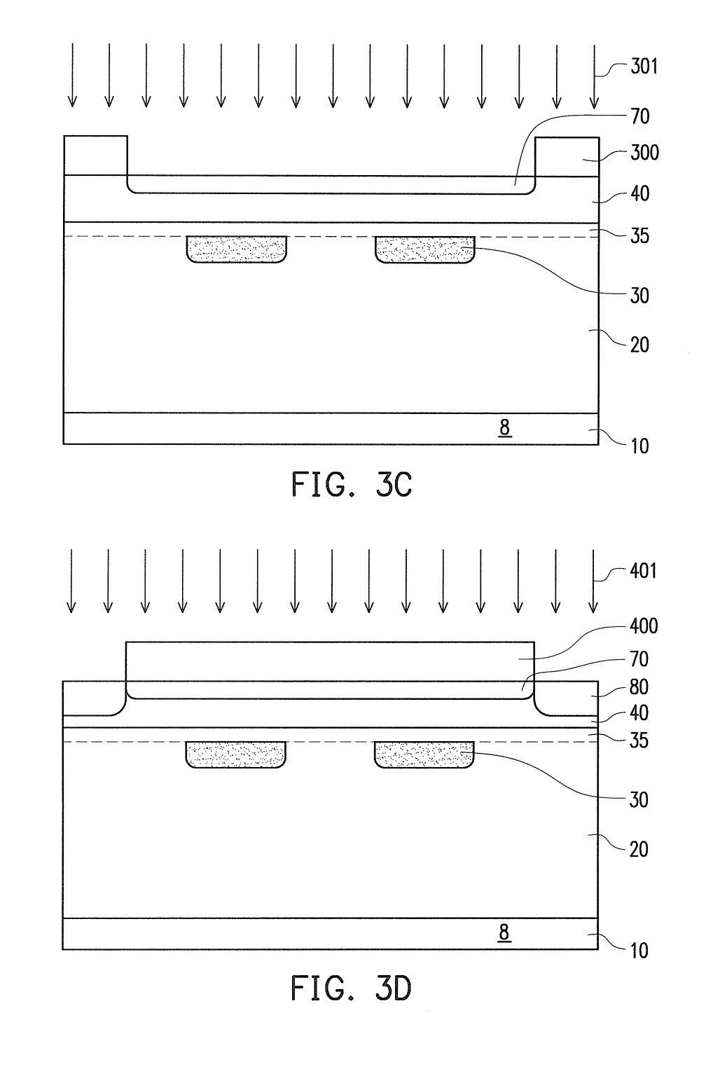

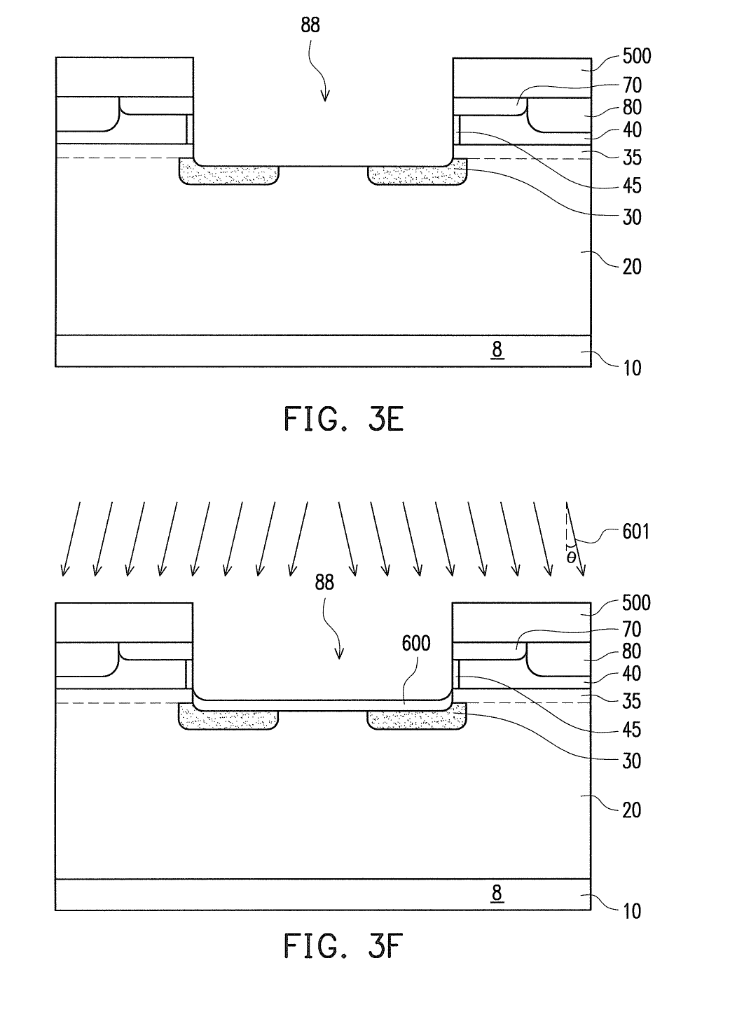

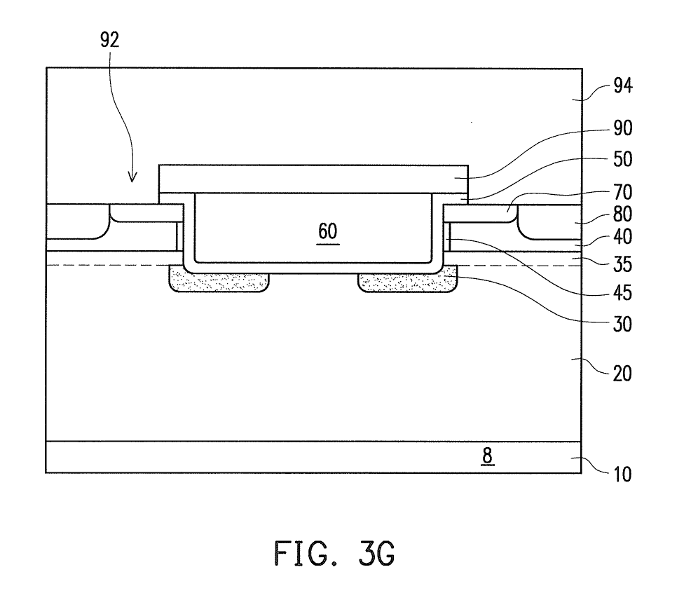

FIGS. 3A-3G are cross-sectional views illustrating a flow of fabricating a SiC trench gate transistor with segmented field shielding region according to an embodiment of the disclosure.

Referring to FIG. 3A, the substrate 8 is, for example, a 4H—SiC substrate, and is of the first conductivity type to serve as the drain region 10. In the embodiment, the first conductivity type of the substrate 8 is an n-type, which is, for example, doped with nitrogen, and a doping concentration thereof is, for example, 1×10¹⁹ cm⁻³.

Then, the first drift layer 20 is formed on the substrate 8. In the embodiment, the first drift layer 20 of the first conductivity type is an n-type SiC epitaxial layer, which is, for example, doped with phosphorus, a doping concentration thereof is, for example, 6×10¹⁵ cm⁻³, and a thickness thereof is, for example, 8.5 μm.

Then, a mask layer 100 is first formed on the first drift layer 20, and then an ion implantation process 101 is performed to fault the segmented field shielding regions 30 in the first drift layer 20. In the embodiment, the segmented field shielding region 30 is of the second conductivity type, the implanted dopant is p-type, for example, aluminium, a doping concentration thereof is, for example, 2.0×10¹⁸-1.0×10¹⁹ cm⁻³, and a junction depth thereof is, for example, 0.5-0.6 μm.

Thereafter, referring to FIG. 3B, the mask layer 100 is removed. Then, the second drift layer 35 is formed on the first drift layer 20. In the embodiment, the second drift layer 35 is of the first conductivity type, and a material of the second drift layer 35 can be an n-type SiC epitaxial layer, which is, for example, doped with phosphorus, a doping concentration thereof is greater than or equal to that of the first drift layer, 20, which is, for example, 6×10¹⁵ cm⁻³, and a thickness thereof is, for example, 1.5 μm.

Another mask layer (not shown) is formed on the second drift layer 35, and an ion implantation process 201 is performed to form the base region 40 in the second drift layer 35. In the embodiment, the base region 40 is of the second conductivity type, the implanted dopant is p-type, for example, boron, a doping concentration thereof is, for example, 8.0×10¹⁶-3.0×10¹⁷ cm⁻³, and a junction depth thereof is, for example, 0.8-1.0 μm. Then, the mask layer (not shown) is removed.

Then, referring to FIG. 3C, a mask layer 300 is formed. Then, an ion implementation process 301 is performed to form a plurality of source regions 70 in the base region 40. In the embodiment, the source region 70 is of the first conductive type, the implanted dopant is n-type, for example, nitrogen, a doping concentration thereof is, for example, 1.0×10¹⁹-5.0×10¹⁹ cm⁻³, and a junction depth thereof is, for example, 0.2-0.4 μm.

Then, referring to FIG. 3D, the mask layer 300 is removed, and a mask layer 400 is formed. Then, an ion implantation process 401 is performed to form a plurality of body region 80 in the base region 40. In the embodiment, the body region 80 has the second conductivity type, the implanted dopant is p-type, for example, aluminium, a doping concentration thereof is, for example, 1.0×10¹⁹-5.0×10¹⁹ cm⁻³, and a junction depth thereof is, for example, 0.4-0.6 μm.

Then, referring to FIG. 3E, the mask layer 400 is removed, and a mask layer 500 is formed. Then, an etching process is performed to removed a part of the source region 70, the base region 40, the second drift layer 35 and the first drift layer 20 to form the gate trench 88, and expose a plurality of the segmented field shielding regions 30 and the first drift layer 20.

Then, referring to FIG. 3F, a resist layer 600 is formed on the bottom of the gate trench 88 to cover a bottom surface of the gate trench 88 and expose the sidewall of the gate trench 88. In the embodiment, a thickness of the resist layer 600 is, for example, 400 nm, and a surface of the resist layer 600 is slightly lower than a bottom surface of the base region 40. A method of foaming the resist layer 600 is as follows. A photoresist layer is first coated and planarized, and then anisotropic etching is performed to remove the photoresist layer outside the bottom of the gate trench 88.

Then, a tilt angle ion implantation process 601 is performed to foam the embedded channel 45 under the source region 70 and in the base region 40 on the sidewall of the gate trench 88. In the embodiment, the embedded channel 45 is of the first conductive type, for example, n-type channel. A tilt angle θ of the tilt angle ion implantation process 601 is less than 10°, which is, for example, 7°, and the implanted n-type dopant is, for example, nitrogen or phosphorus, and a doping concentration thereof is, for example, 4.0×10¹⁶-2.0×10¹⁷ cm⁻³, and a thickness of the embedded channel 45 is, for example, 30-80 nm.

Then, the resist layer 600 is removed, and a layer of carbon film is covered. In the embodiment, a thick photoresist layer is coated, and then a high temperature of 600° C. is applied to form the carbon film (not shown). Then, an anneal process is performed at a high temperature of 1700° C., so as to activate the dopants implanted in the aforementioned steps (for example, the dopants in the embedded channel 45, the source region 70, the base region 40, the body region 80 and the segmented field shielding region 30). Then, the carbon film is removed, and an oxidation process is performed to form a sacrificial oxide layer (not shown). Then, the sacrificial oxide layer is removed to remove defects on the surface of the gate trench 88 to smooth the sidewall.

Then, referring to FIG. 3G, the gate dielectric layer 50 is formed on the sidewall and the bottom of the gate trench 88. In the embodiment, the gate dielectric layer 50 is an oxide layer formed through a wet oxidation growth process at 1150° C., and a thickness thereof is, for example, 50-100 nm. Then, an anneal process is performed in atmosphere of NO and N₂O.

Then, the trench gate 60 is formed in the gate trench 88. In the embodiment, a material of the trench gate 60 is n-type doped poly-Si. A method of forming the trench gate 60 is, for example, to deposit the poly-Si through a chemical vapor deposition method. The n-type dopant of the poly-Si is introduced thereinto by using a gas, for example, POCl₃ during the deposition, a temperature is, for example, 650-850° C., and a doping concentration is, for example, 1.0×10¹⁹-5.0×10¹⁹ cm⁻³. Then, a mask layer (not shown) is formed, and an anisotropic etching is performed to remove the n-type doped poly-Si outside the gate trench 88 and located at the region that is not covered by the mask layer (not shown). Then, the mask layer (not shown) is removed.

Then, a passivation layer 90 is fanned. A material of the passivation layer is, for example, silicon nitride (SiNx), low temperature silicon oxide, or silicon oxide formed by tetraethoxysilane (TEOS) serving as a reaction gas, or a stacked layer formed by a combination of silicon nitride and silicon oxide. In the silicon nitride (SiNx), a proportion x of nitrogen and oxygen can be any possible stoichiometric coefficient. Then, a contact opening 92 is formed in the passivation layer 90. A method of forming the contact opening 92 is, for example, to form a mask layer (not shown) on the passivation layer 90, and then the anisotropic etching is performed to expose the source region 70, the body region 80 and the gate 60 (not shown). Then, a conductive layer 94 is formed on the passivation layer 90 and in the contact opening 92, and the conductive layer 94 is patterned to form an electrode. The conductive layer 94 can be metal, metal alloy, metal nitride or a combination thereof, for example, a stacked layer of Ti and Al or a stacked layer of Ti, TiN and Al.

### Example 1

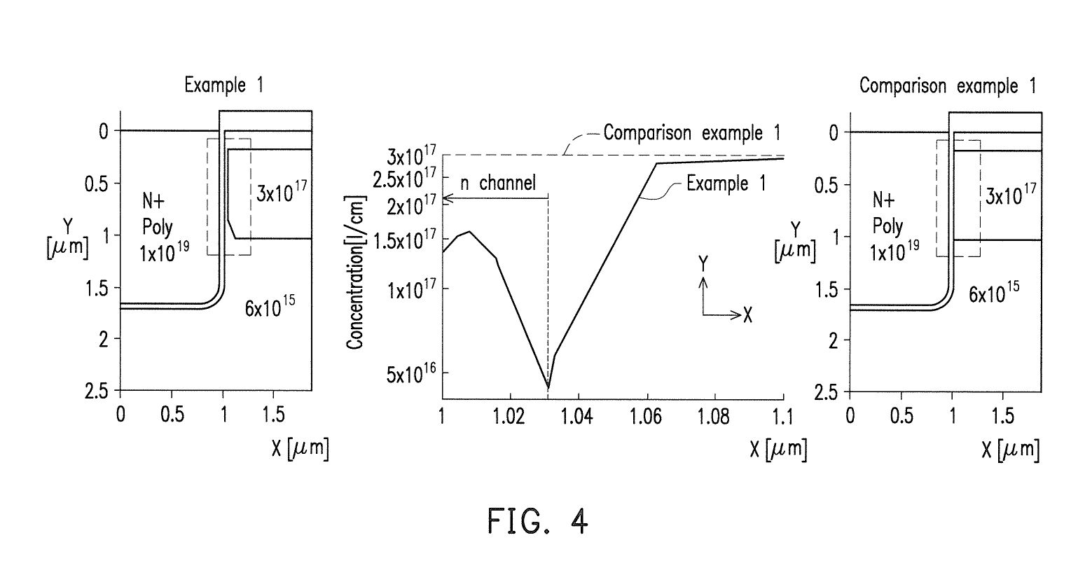

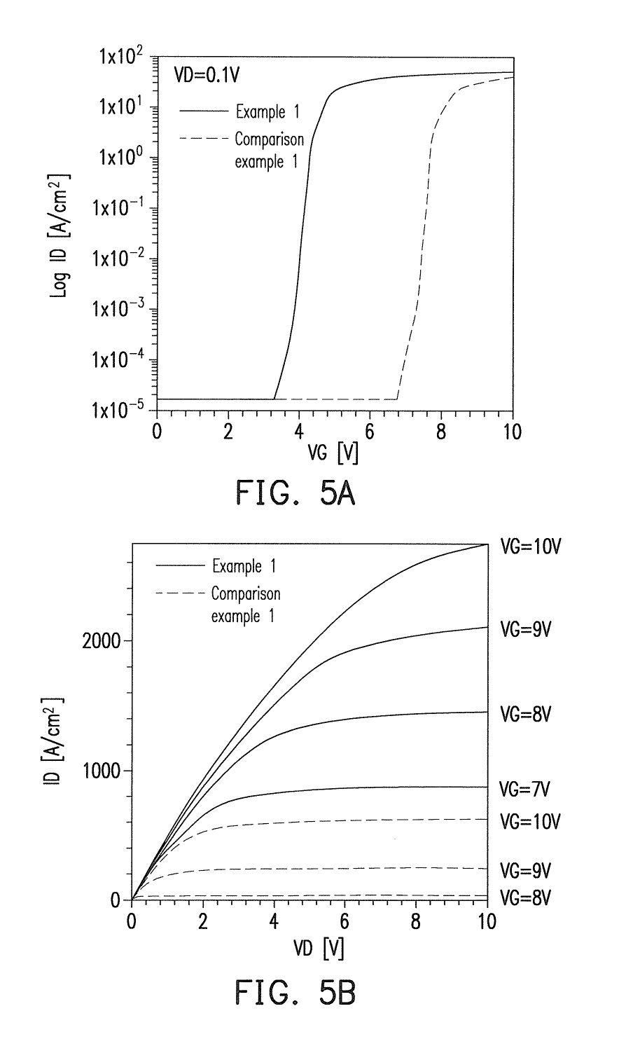

A SiC trench gate transistor with segmented field shielding region is fabricated according to the aforementioned method, where the substrate is the 4H—SiC substrate. A thickness of the base layer is 1 μm and the doping concentration thereof is 3×10¹⁷ cm⁻³, a doping concentration of the first drift layer is 6×10¹⁵ cm³, a depth of the source region is 0.2˜0.3 μm, the gate dielectric layer is silicon oxide, and a thickness thereof is 50 nm. The n-type embedded channel is formed through ion implantation with a dose of 1×10¹⁴ cm⁻², energy of 80 KeV, and a tilt angle of 7°. At a place having a distance of 0.75 μm from the surface of the source region, a doping concentration of the surface of the gate oxide layer is simulated in FIG. 4, after the gate oxide layer is formed, the n-type embedded channel with a thickness of 30 nm is formed. A simulation result of a characteristic curve of a drain current (ID) and a gate voltage (VG) in case of a drain voltage of 0.1V is shown in FIG. 5A. A simulation result of characteristic curves of the drain current (ID) and the drain voltage (VD) under various gate voltages (VG) is shown in FIG. 5B.

### Comparison Example 1

A SiC trench gate transistor with segmented field shielding region is fabricated according to the method of the example 1, though the ion implantation process of the n-type embedded channel is omitted. At a place having a distance of 0.75 μm from the surface of the source region, a doping concentration of the surface of the gate oxide layer is simulated in FIG. 4. A simulation result of a characteristic curve of the drain current (ID) and the gate voltage (VG) in case of the drain voltage of 0.1V is shown in FIG. 5A. A simulation result of characteristic curves of the drain current (ID) and the drain voltage (VD) under various gate voltages (VG) is shown in FIG. 5B.

As shown in FIG. 4, the example 1 having the n-type embedded channel is still fully depleted when the gate voltage VG=0V, which has an effect of decreasing a threshold voltage. As shown in FIG. 5A, the threshold voltage of the comparison example 1 without the ion implantation is 6.87V, and the threshold voltage of the example 1 in which the n-type embedded channel is formed through tilt angle ion implantation is decreased to 4.38V (when the drain voltage VD=0.1V), and is still maintained to an enhancement type MOS. As shown in FIG. 5B, the example 1 of forming the n-type embedded channel on the sidewall of the gate trench through the tilt angle ion implantation can greatly increase a turn-on current.

### Example 2

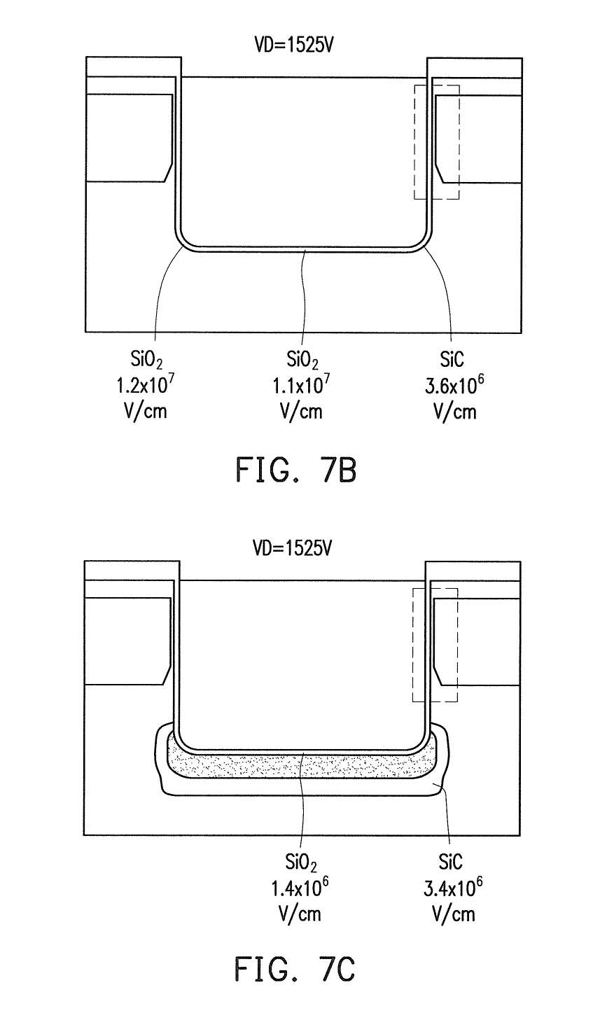

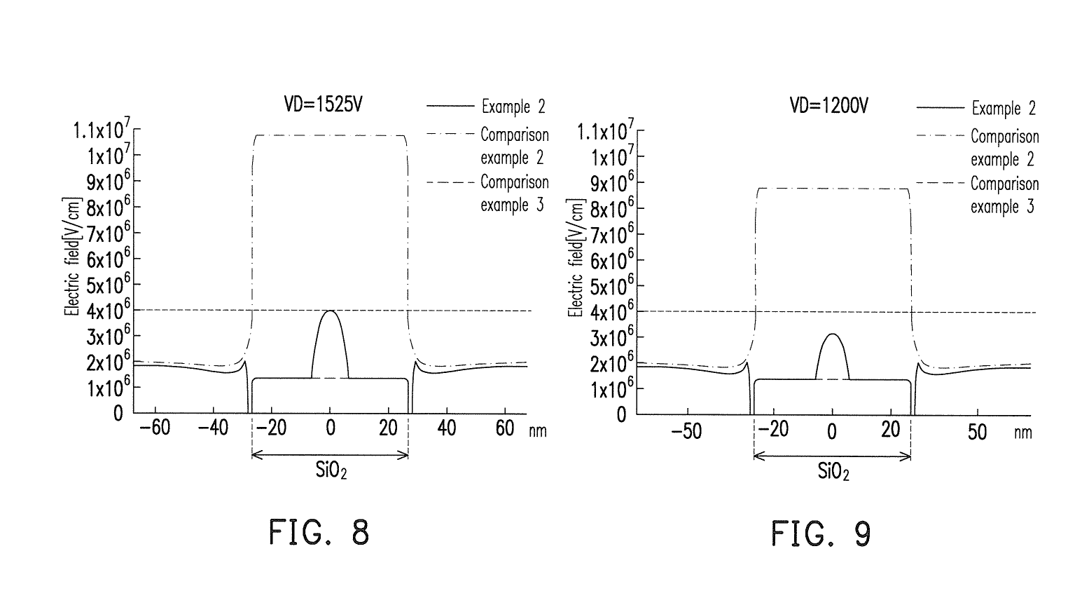

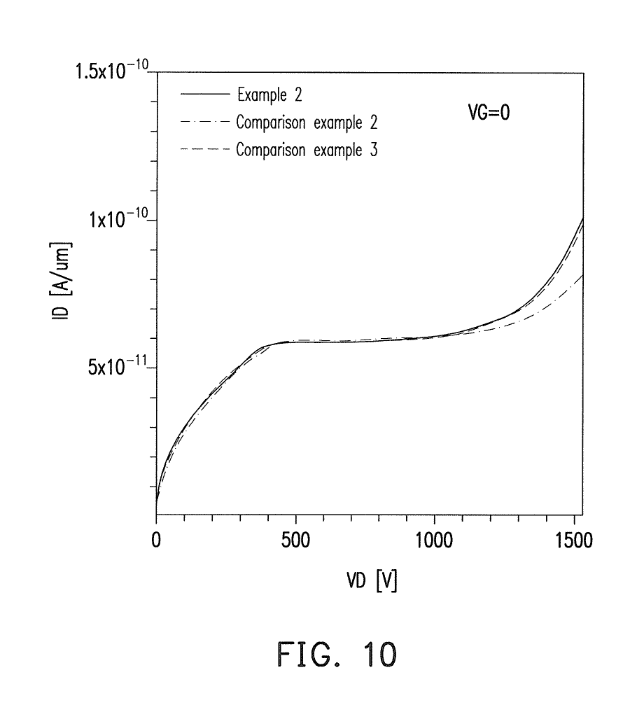

A SiC trench gate transistor with segmented field shielding region is fabricated according to the aforementioned method, where the segmented P+ field shielding regions are located under the bottom of the gate trench, and a pitch between two adjacent P+ field shielding regions is 1.5 μm. A simulation result of a field strength at peripheral of the gate trench in case that the gate voltage VG=0V and the drain voltage is a breakdown voltage (i.e. VD=1525V) is shown in FIG. 7A. Simulation results of a field strength distribution of the gate dielectric layer on the bottom of the gate trench (a place having a distance of 1.675 μm from the top of the gate trench) in case that the drain voltage is the breakdown voltage (i.e. VD=1525V) and the drain voltage is a rated voltage (i.e., VD=1200V) during turn-off are shown in FIG. 8 and FIG. 9 respectively. A simulation result of characteristic curves of the drain current (ID) and the drain voltage (VD) during turn-off is shown in FIG. 10.

Comparison Example 2

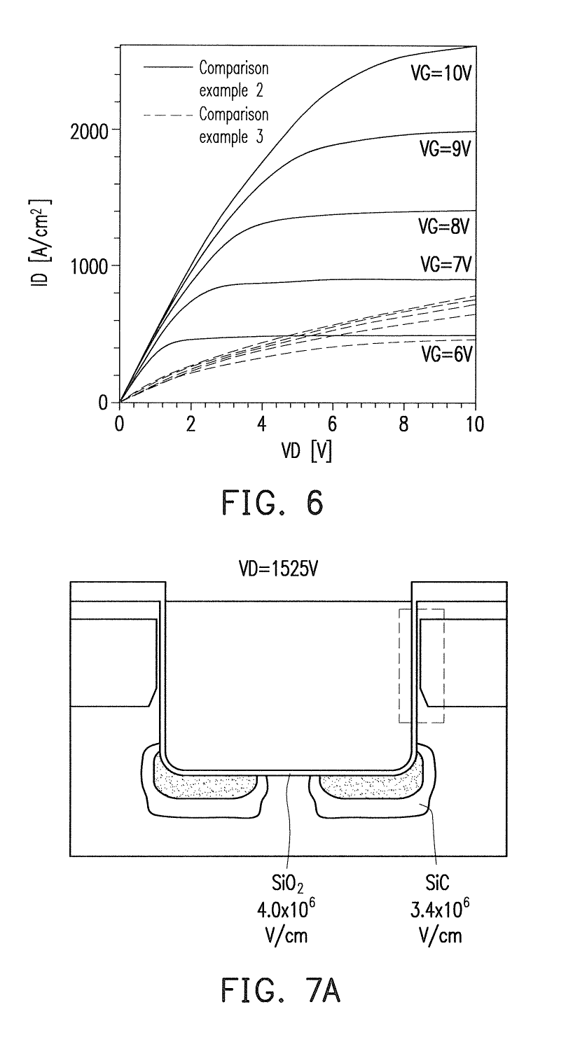

A SiC trench gate transistor with segmented field shielding region is fabricated according to the aforementioned method, though none segmented P+ field shielding region is located under the bottom of the gate trench. A simulation result of characteristic curves of the drain current (ID) and the drain voltage (VD) under various gate voltages (VG) is shown in FIG. 6. A simulation result of a field strength at peripheral of the gate trench in case that the gate voltage VG=0V and the drain voltage is the breakdown voltage (i.e. VD=1525V) is shown in FIG. 7B. Simulation results of a field strength distribution of the gate oxide layer on the bottom of the gate trench (a place having a distance of 1.675 μm from the top of the gate trench) in case that the drain voltage is the breakdown voltage (i.e. VD=1525V) and the drain voltage is the rated voltage (i.e., VD=1200V) during turn-off are shown in FIG. 8 and FIG. 9 respectively. A simulation result of a characteristic curve of the drain current (ID) and the drain voltage (VD) during turn-off is shown in FIG. 10.

### Comparison Example 3

A SiC trench gate transistor with segmented field shielding region is fabricated according to the aforementioned method, though the bottom of the gate trench is completely covered by the P+ field shielding region. A simulation result of characteristic curves of the drain current (ID) and the drain voltage (VD) under various gate voltages (VG) is shown in FIG. 6. A simulation result of a field strength at peripheral of the gate trench in case that the gate voltage VG=0V and the drain voltage is the breakdown voltage (i.e. VD=1525V) is shown in FIG. 7C. Simulation results of a field strength distribution of the gate oxide layer on the bottom of the gate trench (a place having a distance of 1.675 μm from the top of the gate trench) in case that the drain voltage is the breakdown voltage (i.e. VD=1525V) and the drain voltage is the rated voltage (i.e., VD=1200V) during turn-off are shown in FIG. 8 and FIG. 9 respectively. A simulation result of a characteristic curve of the drain current (ID) and the drain voltage (VD) during turn-off is shown in FIG. 10.

As shown in FIG. 6, when the bottom of the gate trench is completely covered by the P+ field shielding region (the comparison example, 3), a series-connected resistor formed of the JFET between the P+ field shielding region and the body region may greatly limit the turn-on current.

As shown in FIG. 7B, in the comparison example 2 without the P+ field shielding region, field strengths of the gate oxide layer at the bottom and the bottom corner of the gate trench are respectively 1.1×10⁷ and 1.2×10⁷ V/cm, which have exceed the breakdown field thereof (about 4×10⁶ V/cm). As shown in FIG. 7C, in the comparison example 3 that the bottom of the gate trench is completely covered by the P+ field shielding region, the field strength of the gate oxide layer at the bottom and the bottom corner of the gate trench can be decreased to be less than 1.4×10⁶ V/cm. As shown in FIG. 7A, in the example 2 that the pitch of the segmented P+ field shielding regions is 1.5 μm, a maximum field strength of the gate oxide layer at the bottom of the gate trench in the center without the segmented P+ field shielding region is still maintained to be less than or equal to the breakdown field 4×10⁶ V/cm thereof.

As shown in FIG. 8, during turn-off, when the drain voltage is the breakdown voltage (i.e. VD=1525V), the field strengths at the bottom of the gate trench can all be effectively decreased when the segmented P+ field shielding regions are configured under the bottom of the gate trench (example 2) and when the P+ field shielding region completely covers the bottom of the gate trench (the comparison example 3). As shown in FIG. 9, during turn-off, when the drain voltage is the rated voltage (i.e. VD=1200V), in the example 2 that the segmented P+ field shielding regions are configured, a maximum field strength of the gate oxide layer at the bottom of the gate trench in the center without the segmented P+ field shielding region is more less than the breakdown field thereof.

As shown in FIG. 10, during turn-off, the characteristic curves of the example 2 having the segmented P+ field shielding regions under the bottom of the gate trench and the comparison example 3 having the P+ field shielding region completely covering the bottom of the gate trench are almost the same. Moreover, in case of breakdown, VD=1525V, and positions of the maximum field of SiC are all located at the edge of the P+ field shielding region. Since a breakdown mechanism of the gate oxide layer is not contained in simulation, during turn-off, a leakage current of the comparison example 2 without the P+ field shielding region is underestimated.

In the fabrication method of the disclosure, the segmented P+ field shielding regions are first fabricated in the first drift layer through the ion implantation method, which is different from the method of conducting the p-type ion implantation with high dose and high energy to the entire bottom of the gate trench, so as to avoid a situation that the sidewall of the gate trench is implanted by scattered p-type ions to cause a variation of the turn-on threshold voltage, and decrease a parasitic resistance effect of the JFET. Moreover, through photoresist refill for planarization and anisotropic etching, the resist layer is formed on the bottom surface of the gate trench to protect the P+ field shielding region at the bottom of the gate trench, and the n-type embedded channel is formed on the sidewall of the gate trench through the tilt angle ion implantation.

In summary, the trench gate transistor of the disclosure may effectively decrease the field strengths of the gate oxide layer at the bottom and bottom corner of the gate trench without the field shielding region through the structure of the segmented field shielding regions, so as to improve reliability. Moreover, the structure of the segmented field shielding regions can decrease a parasitic resistance that forms the JFET with the base region. Moreover, the embedded channel is formed on the sidewall of the gate trench through the tilt angle ion implantation, by which the turn-on threshold voltage can be effectively adjusted (decreased) to enhance channel electron mobility, so as to decrease the turn-on resistance. Moreover, the method of fabricating the trench gate transistor with segmented field shielding region of the disclosure is easy, which can be implemented through existent fabrication techniques.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A trench gate transistor with segmented field shielding region, comprising:
a drain region, being of a first conductivity type, and located in a substrate;
a first drift layer, being of the first conductivity type, and located on the substrate;
a second drift layer, being of the first conductivity type, and located on the first drift layer
a plurality of base regions, being of a second conductivity type, and located on the second drift layer, wherein a plurality of gate trenches are located between the base regions;
a plurality of source regions, being of the first conductivity type, and disposed in the base regions and located adjacent to sidewalls of the gate trenches;
a plurality of body regions, being of the second conductivity type, and disposed in the base regions;
a plurality of segmented field shielding regions, being of the second conductivity type, and disposed under a bottom of the gate trenches;
a plurality of gate dielectric layers, disposed on the bottom and at the sidewall of the gate trench; and
a plurality of trench gates, located in the gate trenches.

2. The trench gate transistor with segmented field shielding region as claimed in claim 1, wherein depths of the gate trenches are equal to or greater than that of a bottom of the second drift layer.

3. The trench gate transistor with segmented field shielding region as claimed in claim 1, wherein the source region surrounds the body region.

4. The trench gate transistor with segmented field shielding region as claimed in claim 1, further comprising an embedded channel of the first conductivity type and located under the source region and in the base region on the sidewall of the gate trench.

5. The trench gate transistor with segmented field shielding region as claimed in claim 1, wherein the first conductivity type is an n-type, and the second conductivity type is a p-type.

6. The trench gate transistor with segmented field shielding region as claimed in claim 1, wherein each of the segmented field shielding regions extends and covers a bottom corner of the gate trench or extends to the bottom of the base region.

7. A method of fabricating a trench gate transistor with segmented field shielding region, comprising:
forming a drain region in a substrate, wherein the drain region is of a first conductivity type;
forming a first drift layer on the substrate, wherein the first drift layer is of the first conductivity type;
forming a plurality of segmented field shielding regions that are floating in a first drift region, wherein the segmented field shielding regions are of a second conductivity type;
forming a second drift layer on the first drift layer, wherein the second drift layer is of the first conductivity type;
forming a base region in the second drift layer, wherein the base region is of the second conductivity type;
forming a source region in the base region, wherein the source region is of the first conductivity type;
removing a part of the source region, the base region and the second drift layer to form a gate trench;
forming a gate dielectric layer at a sidewall and on a bottom surface of the gate trench; and
forming a trench gate in the gate trench.

8. The method of fabricating the trench gate transistor with segmented field shielding region as claimed in claim 7, further comprising forming a body region in the base region, wherein the body region is surrounded by the source region.

9. The method of fabricating the trench gate transistor with segmented field shielding region as claimed in claim 7, further comprising performing a tilt angle ion implantation process before the gate dielectric layer is formed, so as to form an embedded channel under the source region and in the base region at the sidewall of the gate trench.

10. The method of fabricating the trench gate transistor with segmented field shielding region as claimed in claim 9, further comprising covering a resist layer on the bottom surface of the gate trench before the tilt angle ion implantation process is performed.

11. The method of fabricating the trench gate transistor with segmented field shielding region as claimed in claim 9, wherein a tilt angle of the tilt angle ion implantation process is an included angle of an implantation direction and the sidewall of the gate trench, and is not more than 10°.
